(19) United States
(12) Patent Application Publication
(10) Pub. No.: US 2026/0262168 A1
(43) Pub. Date: Sep. 3, 2026

(54) MULTILAYER CIRCUIT BOARD

(71) Applicant: FUJIFILM Corporation, Tokyo (JP)

(72) Inventors: Junji HAYASHI, Saitama (JP); Azusa ONOKI, Saitama (JP); Taku UNNO, Saitama (JP); Masahiko MIYATA, Saitama (JP)

(73) Assignee: FUJIFILM Corporation, Tokyo (JP)

(21) Appl. No.: 19/548,918

(22) Filed: Feb. 24, 2026

(30) Foreign Application Priority Data
Feb. 28, 2025 (JP) 2025-031684

(51) Int. Cl. H05K 1/181; H05K 1/11

(52) U.S. Cl. CPC H05K 1/181; H05K 1/116; H05K 2201/066; H05K 2201/10151; H05K 2201/10409

(57) ABSTRACT

A surface layer of the multilayer circuit board on which a gyro sensor is mounted includes a specific region corresponding to an installation region of the gyro sensor as seen in a lamination direction. At least a portion of a wiring pattern routed from a terminal land of the gyro sensor is not formed in the specific region.

### CROSS-REFERENCE TO RELATED APPLICATIONS

The present application claims priority under 35 U.S.C. §119 to Japanese Patent Application No. 2025- 031684, filed on February 28, 2025. The above application is hereby expressly incorporated by reference, in its entirety, into the present application.

### BACKGROUND

### Technical Field

The present disclosed technology relates to a multilayer circuit board.

### Description of the Related Art

Described in JP2012-058519A is an electronic device including a board, a shake detection sensor, and a vibration electronic component. Electronic components can be mounted on a first mounting surface of the board and a second mounting surface which is a surface opposite to the first mounting surface. The shake detection sensor is mounted on the first mounting surface of the board. The vibration electronic component is mounted on the second mounting surface of the board and vibrates in a case where a voltage is applied to the vibration electronic component. The vibration electronic component is mounted on the second mounting surface of the board without being mounted in a region that is opposite to a region in which the shake detection sensor is mounted.

Described in JP2019-145683A is an electronic circuit board, the electronic circuit board including a board that has a multilayer structure including at least one ground layer and an oscillator circuit that is provided on the board and that includes an oscillator and a circuit including an amplifier connected to a signal terminal of the oscillator. The electronic circuit board has at least one of a first ground electrode structure in which a ground layer of the multilayer structure that is closest to the signal terminal has a region that overlaps with the signal terminal in a plan view as seen in a direction perpendicular to a board surface and in which no ground electrode is formed, a second ground electrode structure in which a ground layer of the multilayer structure that is closest to a first wire connecting the signal terminal and an input portion of the amplifier to each other has a region that overlaps with the first wire in the plan view and in which no ground electrode is formed, or a third ground electrode structure in which a ground layer of the multilayer structure that is closest to a second wire connecting the signal terminal and an output portion of the amplifier to each other has a region that overlaps with the second wire in the plan view and in which no ground electrode is formed.

Described in JP2016-189385A is an electronic device including a multilayer board on which an electronic component serving as a heat source is mounted, on which a first ground pattern for electrical connection to the electronic component is provided, and to which a metal chassis is fixed by means of a metal screw. On the multilayer board, a second ground pattern for electrical connection to the chassis is provided in a region where the chassis is fixed by the screw. An insulation portion is provided between the second ground pattern and the first ground pattern. The first ground pattern and the second ground pattern are electrically connected via a connection pattern that leads from the second ground pattern and that is connected to the first ground pattern. No conductive pattern is provided in a region corresponding to the second ground pattern on each of layers of the multilayer board excluding a layer provided with the second ground pattern.

Described in JP2011-151538A is a board structure for a dome-shaped surveillance camera composed of at least a lens that is surrounded by a dome and a housing cover enabling an electromagnetic shield and that is disposed in the dome, a sensor board that captures a subject image incident through the dome and the lens disposed in the housing cover and that outputs an electric signal, a camera digital signal processor (DSP) board that performs an image correction process on the electric signal, a main board that performs compression encoding of the signal subjected to the image correction process, a local area network (LAN) board that outputs the signal subjected to the compression encoding to the outside, a spacer that mechanically bonds the sensor board and the camera DSP board to form a composite body with two upper and lower circuit boards, a rolling fixation metal fitting for attachment of the composite body and rotation in a pan direction, and a tilt metal fitting that is attached to a rolling metal fitting and that rotates the composite body in a tilt direction. The composite body is disposed in the housing cover while being interposed vertically between the tilt metal fitting and the rolling fixation metal fitting. A dome side of the composite body is the sensor board formed with a frame ground and a side of the composite body that is far from the dome is the camera DSP board formed with a frame ground.

### SUMMARY

One embodiment according to the present disclosed technology provides a multilayer circuit board with which it is possible to stabilize vibration characteristics.

According to an aspect of the present disclosure, there is provided a multilayer circuit board including a gyro sensor mounted on a first layer, in which at least a portion of a wiring pattern routed from a terminal land of the gyro sensor is not formed in a specific region of the first layer, the specific region corresponding to an installation region of the gyro sensor as seen in a lamination direction.

It is preferable that the terminal land is formed at the first layer, the wiring pattern is formed at a layer different from the first layer, and the terminal land and the wiring pattern are connected to each other via a conduction hole.

It is preferable that a conductive plane is not present in the specific region.

It is preferable that the specific region includes a region inside the installation region and a region outside the installation region.

It is preferable that the specific region is a region obtained by multiplying the installation region by a set scale factor.

It is preferable that the terminal land is formed at the first layer, and the installation region includes the terminal land.

It is preferable that a vibration transmission suppressing pattern is formed around the installation region of the first layer.

It is preferable that a plurality of vibration transmission suppressing patterns are formed.

It is preferable that the vibration transmission suppressing pattern includes a curved portion.

It is preferable that a layer that functions as a shield for a wiring pattern causing a noise is provided.

It is preferable that a heat generating component is mounted on the first layer in addition to the gyro sensor, and a heat radiation mechanism that radiates heat of the heat generating component to an outside is provided.

It is preferable that a board fixation portion is provided within a set distance from the gyro sensor.

It is preferable that the multilayer circuit board is built into an imaging apparatus or an interchangeable lens.

### BRIEF DESCRIPTION OF THE DRAWINGS

Exemplary embodiments according to the technique of the present disclosure will be described in detail based on the following figures, wherein:

FIG. 1 is a perspective view of an imaging apparatus;

FIG. 2 is a view showing a multilayer circuit board built into an interchangeable lens;

FIG. 3 is a cross-sectional view of the multilayer circuit board;

FIG. 4 is a view showing a configuration of a gyro sensor and the state of connection between the gyro sensor and the multilayer circuit board;

FIG. 5 is a top view of a surface layer in the vicinity of an installation region of the gyro sensor;

FIG. 6 is a top view of an inner layer adjacent to the surface layer in the vicinity of the installation region of the gyro sensor;

FIG. 7 is a top view of a surface layer in the vicinity of an installation region of a gyro sensor of a second embodiment;

FIG. 8 is a top view of an inner layer and a rear layer in the vicinity of the installation region of the gyro sensor of the second embodiment;

FIG. 9 is a view showing an inner layer that functions as a shield for a wiring pattern causing a noise;

FIG. 10 is a view showing a vibration transmission suppressing pattern;

FIG. 11 is a view showing two vibration transmission suppressing patterns;

FIG. 12 is a view showing a vibration transmission suppressing pattern including a curved portion;

FIG. 13 is a view showing a heat radiation mechanism; and

FIG. 14 is a view showing how the multilayer circuit board is built into the imaging apparatus

### DETAILED DESCRIPTION

### First Embodiment

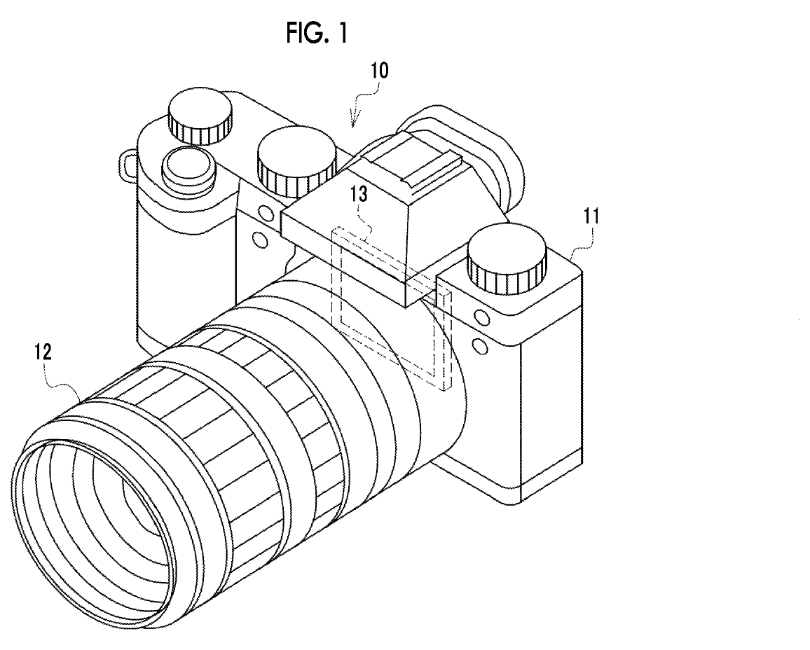

For example, as shown in FIG. 1, an imaging apparatus 10 is, for example, a single-lens digital camera, and includes an apparatus main body 11 and an interchangeable lens 12. An upper surface of the apparatus main body 11 is provided with various operation members including a release button. In addition, a rear surface of the apparatus main body 11 is provided with a liquid crystal monitor, a viewfinder, a menu key, a cross key, and the like (all of which are not shown). The interchangeable lens 12 has a configuration in which a plurality of lenses such as an objective lens, a focus lens, and a zoom lens are combined with each other. Note that the imaging apparatus 10 is not limited to the above-described single-lens digital camera and may be a digital still camera, a smartphone, a tablet terminal, or the like.

A front surface of the apparatus main body 11 is provided with a mount (not shown). The interchangeable lens 12 is attachably and detachably connected to the apparatus main body 11 via the mount. The mount has a structure (for example, a bayonet structure) provided to reliably fix the interchangeable lens 12 to the apparatus main body 11. In addition, the mount has an electric contact point that is for transmission of electric signals between the apparatus main body 11 and the interchangeable lens 12.

An imaging element 13 provided to capture a subject image taken in through the interchangeable lens 12 is built into the apparatus main body 11. The imaging element 13 is, for example, a charge coupled device (CCD) image sensor or a complementary metal oxide semiconductor (CMOS) image sensor.

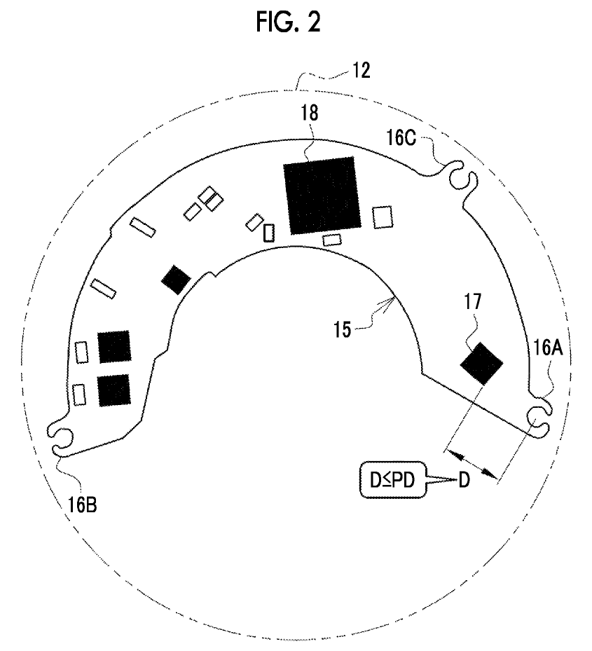

For example, as shown in FIG. 2, a multilayer circuit board 15 is disposed in the interchangeable lens 12. The multilayer circuit board 15 has a fan-like shape that conforms to the cylindrical shape of the interchangeable lens 12. The multilayer circuit board 15 includes board fixation portions 16A, 16B, and 16C. The board fixation portions 16A and 16B are provided at both ends of the multilayer circuit board 15. The board fixation portion 16C is provided at a position close to the board fixation portion 16A side with respect to the upper center of the multilayer circuit board 15. The board fixation portions 16A to 16C are C-shaped claws that protrude from an outer periphery of the multilayer circuit board 15. The multilayer circuit board 15 is fixed to the interchangeable lens 12 by means of screws (not shown) with rubber bushes that are inserted into the board fixation portions 16A to 16C.

A large number of electronic components such as a gyro sensor 17 and an integrated circuit 18 are mounted on the multilayer circuit board 15. The gyro sensor 17 is mounted at a position on the board fixation portion 16A side. The gyro sensor 17 detects vibration that is applied to the interchangeable lens 12 and to the imaging apparatus 10. The gyro sensor 17 is, for example, a vibration-type gyro sensor. The vibration-type gyro sensor is a gyro sensor that causes a vibrator of a cantilevered beam to vibrate at a predetermined resonance frequency and that detects a Coriolis force generated by the influence of an angular velocity by means of a piezoelectric element or the like. The integrated circuit 18 is mounted at a position slightly close to the board fixation portion 16A side with respect to the center of the multilayer circuit board 15. The integrated circuit 18 controls the driving of the gyro sensor 17 and other electronic components. The integrated circuit 18 is an example of a "heat generating component" according to the embodiment of the present disclosed technology.

The integrated circuit 18 derives the direction of movement and the amount of movement of a shake correction mechanism based on a vibration detection signal from the gyro sensor 17. The shake correction mechanism is, for example, a correction lens moving mechanism that moves a correction lens built into the interchangeable lens 12 along a plane of which the normal line coincides with an optical axis, for example. The shake correction mechanism corrects a shake of a subject image by moving the correction lens in the direction of movement derived by the integrated circuit 18 and by the amount of movement derived by the integrated circuit 18. Note that as the shake correction mechanism, an imaging element moving mechanism that moves the imaging element 13 along a plane of which the normal line coincides with the optical axis may be used. In this case, the integrated circuit 18 transmits the vibration detection signal to the apparatus main body 11 through the electric contact point of the mount.

A distance D between the board fixation portion 16A and the gyro sensor 17 is within a set distance PD (D ≤ PD). The distance D is the shortest distance between the center of a C-shaped portion of the board fixation portion 16A and an outer periphery of the gyro sensor 17. The set distance PD is, for example, 1 mm to 10 mm (1 ≤ PD ≤ 10).

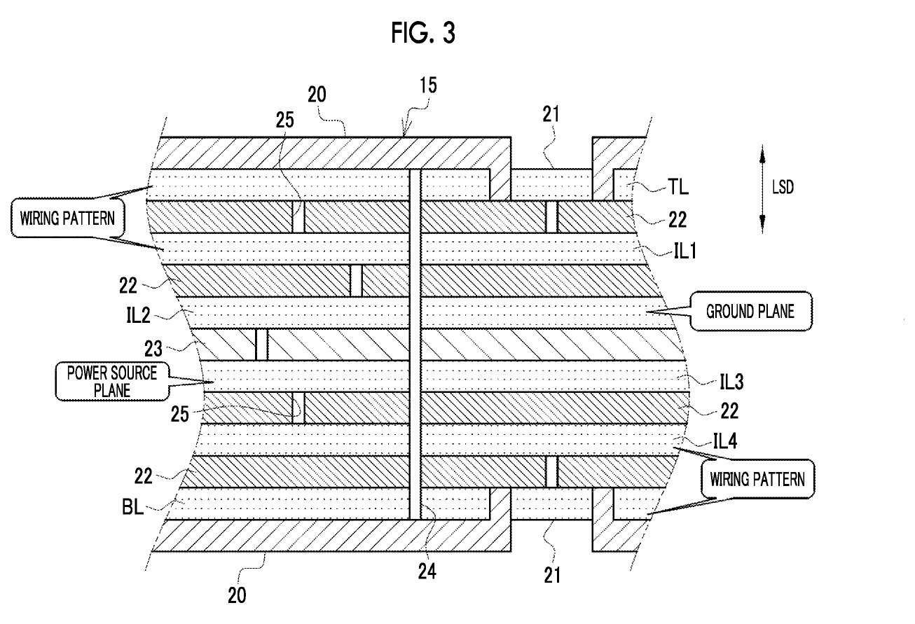

For example, as shown in FIG. 3, the multilayer circuit board 15 has a laminated structure including a surface layer TL, a rear layer BL, and inner layers IL1 to IL4. The surface layer TL, the rear layer BL, and the inner layers IL1 to IL4 are formed of, for example, copper foil. The reference numeral “LSD” represents a lamination direction in which the surface layer TL, the rear layer BL, and the inner layers IL1 to IL4 are laminated.

For example, wiring patterns are formed at the surface layer TL and the rear layer BL, and the inner layers IL1 and IL4. In addition, the inner layer IL2 functions as, for example, a ground plane, and the inner layer IL3 functions as, for example, a power source plane. That is, the inner layers IL2 and IL3 are examples of a “conductive plane” according to the embodiment of the present disclosed technology. Here, a "conductive plane" is a continuous copper foil portion having a relatively large area in which no slit is formed by a wiring pattern or the like. The "conductive plane" is also referred to as a so-called solid pattern. The “conductive plane” is not limited to the above-described ground plane and power source plane, and may be present in a portion of a layer in which a wiring pattern is formed. The number of inner layers is not limited to four as in the above description and may be two, six, eight, or the like.

The surfaces of the surface layer TL and the rear layer BL are covered with resists (solder resists) 20. The resists 20 are made of, for example, epoxy resin. More specifically, the resists 20 are PSR-4000 AM02 manufactured by Taiyo Ink Mfg. Co., Ltd.

The resists 20 protect the wiring patterns formed at the surface layer TL and the rear layer BL. However, terminal lands 21 of the surface layer TL and the rear layer BL are not covered with the resists 20 and are exposed to the outside. The terminal lands 21 are, for example, terminal lands for solder connection of an electronic component. Therefore, the surface layer TL and the rear layer BL are mounting layers for electronic components. The terminal lands 21 are plated with copper, gold, or the like for improvement of solder adhesion. Note that terminal lands for a conductive adhesive such as a silver paste may also be adopted.

Prepregs 22 are disposed between the surface layer TL and the inner layer IL1, between the inner layer IL1 and the inner layer IL2, between the inner layer IL3 and the inner layer IL4, and between the inner layer IL4 and the rear layer BL. Each prepreg 22 bonds two adjacent layers such as the surface layer TL and the inner layer IL1 to each other and insulates such two adjacent layers from each other. The prepreg 22 is, for example, a glass cloth base material obtained by infusing epoxy resin into glass fiber woven into a cloth and causing the epoxy resin to enter a semi-cured state. More specifically, the prepreg 22 is GEA-705G manufactured by Resonac Holdings Corporation.

A core 23 is disposed between the inner layer IL2 and the inner layer IL3. The core 23 is positioned exactly at the center of the laminated structure of the multilayer circuit board 15. The core 23 bonds the inner layer IL2 and the inner layer IL3 to each other and insulates the inner layer IL2 and the inner layer IL3 from each other. The core 23 is a so-called core material, and is provided to increase the stiffness and dimensional stability of the multilayer circuit board 15. The core 23 is, for example, a glass cloth base material obtained by infusing epoxy resin into glass fiber woven into a cloth and causing the epoxy resin to enter a cured state. More specifically, the core 23 is MCL-E-75G manufactured by Resonac Holdings Corporation. Although an example in which only one core 23 is provided has been described, the present disclosed technology is not limited thereto and a plurality of cores 23 may be provided.

The multilayer circuit board 15 includes a through-hole 24 and vias 25 provided in the multilayer circuit board 15. The through-hole 24 and the vias 25 are formed by means of, for example, laser, plasma etching, photolithography, or the like. The through-hole 24 penetrates all the layers of the multilayer circuit board 15 including the surface layer TL, the inner layers IL1 to IL4, the rear layer BL, the prepregs 22, and the core 23. For example, an inner wall of the through-hole 24 is plated with copper. Therefore, the surface layer TL, the inner layers IL1 to IL4, and the rear layer BL are electrically connected to each other through the through-hole 24.

Each via 25 penetrates the prepreg 22 between specific layers such as the surface layer TL and the inner layer IL1 or the core 23. For example, inner walls of the vias 25 are plated with copper. Therefore, layers connected by the vias 25 are electrically connected to each other through the vias 25.

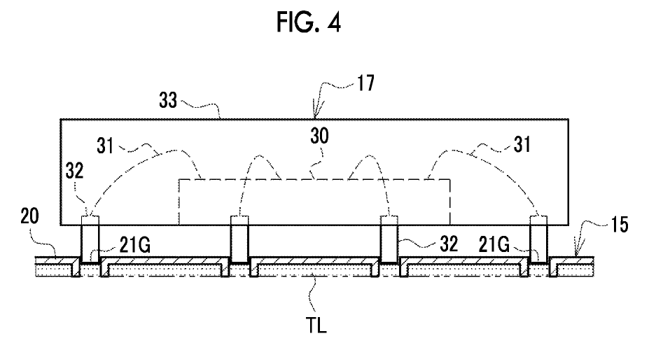

For example, as shown in FIG. 4, the gyro sensor 17 has a structure in which a chip 30, wires 31, and one end (an inner lead) of each of lead frames 32 are encapsulated in a rectangular parallelepiped-shaped mold 33. The mold 33 is made of, for example, epoxy resin. The chip 30 and the like are protected by the mold 33. The chip 30 and the lead frames 32 are connected to each other by the wires 31. The wires 31 are, for example, gold wires. In addition, the lead frames 32 are made of, for example, copper, a copper-nickel alloy, or the like, and are plated with gold or silver.

The other end (an outer lead) of each of the lead frames 32 is exposed to the outside and is soldered to terminal lands 21G of the gyro sensor 17 of the surface layer TL. That is, the gyro sensor 17 is mounted on the surface layer TL. The surface layer TL is an example of a “first layer” according to the embodiment of the present disclosed technology. Note that the terminal lands 21 of electronic components other than the gyro sensor 17, such as the integrated circuit 18, are also formed at the surface layer TL.

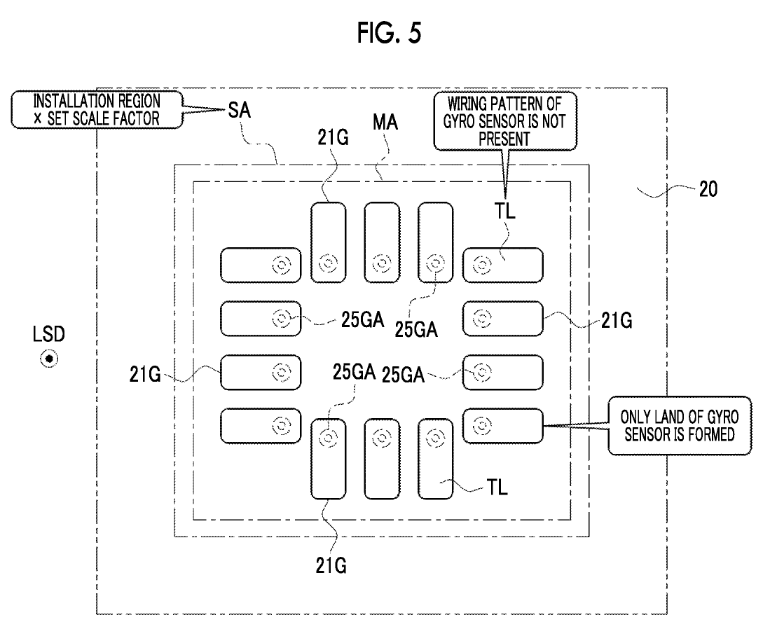

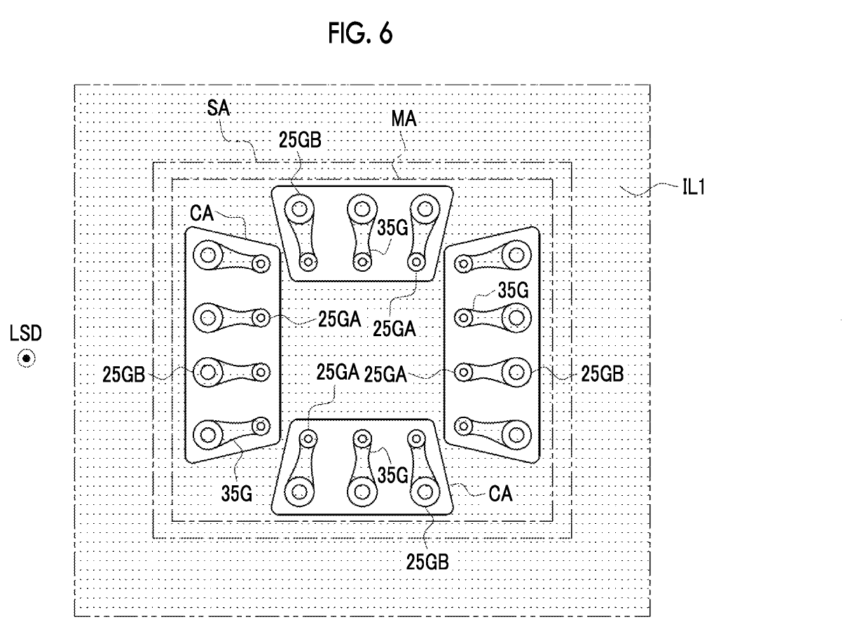

For example, as shown in FIG. 5, on the surface layer TL, only the terminal lands 21G are formed in a specific region SA and wiring patterns 35G (refer to FIG. 6) of the gyro sensor 17, which are routed from the terminal lands 21G, are not formed. The specific region SA is a region corresponding to an installation region MA of the gyro sensor 17. The installation region MA is a region with which the outer shape of the mold 33 of the gyro sensor 17 overlaps in a case where the multilayer circuit board 15 is seen in a lamination direction LSD (a direction perpendicular to the paper surface of FIG. 5). Therefore, the installation region MA has a rectangular shape conforming to the outer shape of the mold 33.

The specific region SA includes a region inside the installation region MA and a region outside the installation region MA. The specific region SA is a region that has the same shape and center as the installation region MA and that is obtained by multiplying the installation region MA by a set scale factor. More specifically, the specific region SA is a region obtained by enlarging or reducing the area of the installation region MA based on the set scale factor. The value of the set scale factor is, for example, equal to or greater than 0.8 and less than 1.2. Therefore, there may be a case where the specific region SA coincides with the installation region MA (the set scale factor of 1.0). The set scale factor is not limited to an area ratio as described above, and may be a magnification ratio. In addition, the installation region MA and the specific region SA do not need to have rectangular shapes as described above. A circular shape, an oval shape, a triangular shape, a pentagonal shape, an octagonal shape, or the like may also be adopted.

The terminal lands 21G of the gyro sensor 17 are included in the installation region MA. In addition, vias 25GA of the gyro sensor 17 are formed below the terminal lands 21G of the gyro sensor 17. Note that although the wiring patterns 35G of the gyro sensor 17 are not formed at the surface layer TL, wiring patterns for electronic components other than the gyro sensor 17, such as the integrated circuit 18, are formed at the surface layer TL.

For example, as shown in FIG. 6, the vias 25GA reach the inner layer IL1 that is adjacent to the surface layer TL and that is immediately below the surface layer TL. The surface layer TL and the inner layer IL1 are electrically connected to each other through the vias 25GA. The vias 25GA are examples of a “conduction hole” according to the embodiment of the present disclosed technology.

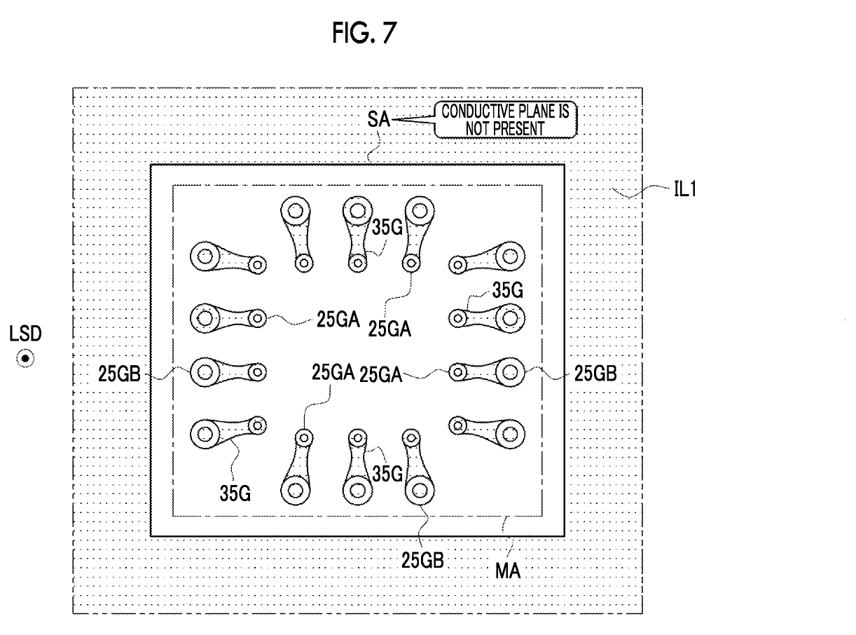

In the inner layer IL1, one end of each of the wiring patterns 35G of the gyro sensor 17 is connected to the via 25GA. The other end of each of the wiring patterns 35G is connected to a via 25GB. Vias 25GB reach the inner layer IL2 from the inner layer IL1. The inner layer IL1 and the inner layer IL2 are electrically connected to each other through the vias 25GB. The vias 25GA and 25GB and the wiring patterns 35G are provided in clearance regions CA where copper foil constituting the inner layer IL1 is not present. The inner layer IL1 functions as a conductive plane in which no wiring pattern is formed in a region other than the clearance regions CA in the vicinity of the specific region SA. The inner layer IL1 is an example of a “layer different from the first layer” according to the embodiment of the present disclosed technology. Note that in FIG. 6, the vias 25GA and 25GB, the wiring patterns 35G, and a region other than the clearance regions CA in which copper foil constituting the inner layer IL1 is present are hatched. The same applies to FIG. 7 and the like which will be described below.

As described above, in the case of the multilayer circuit board 15 of the present disclosure, the wiring patterns 35G routed from the terminal lands 21G of the gyro sensor 17 are not formed in the specific region SA of the surface layer TL on which the gyro sensor 17 is mounted, the specific region SA corresponding to the installation region MA of the gyro sensor 17. Therefore, it is possible to stabilize the vibration characteristics of the multilayer circuit board 15.

The wiring patterns may complicate the vibration characteristics of the multilayer circuit board 15. In particular, the wiring patterns 35G of the gyro sensor 17 which are formed at the surface layer TL on which the gyro sensor 17 is mounted are major factors that cause various vibration modes of the multilayer circuit board 15, together with other factors such as a change in temperature and humidity and the state of soldering between the lead frames 32 and the terminal lands 21G of the gyro sensor 17. In a case where there are various vibration modes and there is no reproducibility, it is difficult to calibrate the output of the gyro sensor 17 in accordance with a vibration mode. Therefore, the output reliability of the gyro sensor 17 is decreased, and as a result, the accuracy of shake correction is also decreased.

However, in the present disclosed technology, the wiring patterns 35G of the gyro sensor 17 are not formed in the specific region SA of the surface layer TL so that the vibration characteristics of the multilayer circuit board 15 are stabilized. Therefore, the reproducibility of the vibration mode of the multilayer circuit board 15 can be improved, and the output of the gyro sensor 17 can be calibrated without any problem. Therefore, it is possible to improve the output reliability of the gyro sensor 17 and the accuracy of shake correction.

In addition, the wiring patterns 35G of the gyro sensor 17 may be formed at the surface layer TL in a region other than the specific region SA. In addition, although an example in which the wiring patterns 35G of the gyro sensor 17 are not formed at all in the specific region SA has been described, a case where at least a portion of the wiring patterns 35G of the gyro sensor 17 is not formed in the specific region SA is also included in the present disclosed technology. In this case as well, an effect in which the vibration characteristics of the multilayer circuit board 15 are stabilized in comparison with a case where all of the wiring patterns 35G of the gyro sensor 17 are formed in the specific region SA can be obtained. In addition, stress applied to the gyro sensor 17 can be reduced in comparison with a case where all of the wiring patterns 35G of the gyro sensor 17 are formed in the specific region SA.

The terminal lands 21G of the gyro sensor 17 are formed at the surface layer TL, and the wiring patterns 35G of the gyro sensor 17 are formed at the inner layer IL1 different from the surface layer TL. In addition, the terminal lands 21G and the wiring patterns 35G are connected to each other through the vias 25GA. Therefore, the terminal lands 21G of the surface layer TL and the wiring patterns 35G formed at the inner layer IL1 without being formed at the surface layer TL can be more easily connected to each other by means of the vias 25GA. A configuration in which the wiring patterns 35G of the gyro sensor 17 are not formed at the surface layer TL can be easily realized.

The specific region SA includes a region inside the installation region MA and a region outside the installation region MA. More specifically, the specific region SA is a region obtained by multiplying the installation region MA by a set scale factor. Therefore, a configuration in which the wiring patterns 35G are not formed in the specific region SA that is considered to influence the gyro sensor 17 can be realized and thus it is possible to easily obtain an effect in which the vibration characteristics of the multilayer circuit board 15 are stabilized.

The installation region MA includes the terminal lands 21G of the gyro sensor 17. Therefore, a region that is considered to influence the gyro sensor 17 can be set as the specific region SA.

As shown in FIG. 2, the multilayer circuit board 15 includes the board fixation portion 16A provided within the set distance PD from the gyro sensor 17. Therefore, it is possible to lower a possibility that the gyro sensor 17 detects vibration of the multilayer circuit board 15 that is caused by distortion or the like of the multilayer circuit board 15.

### Second Embodiment

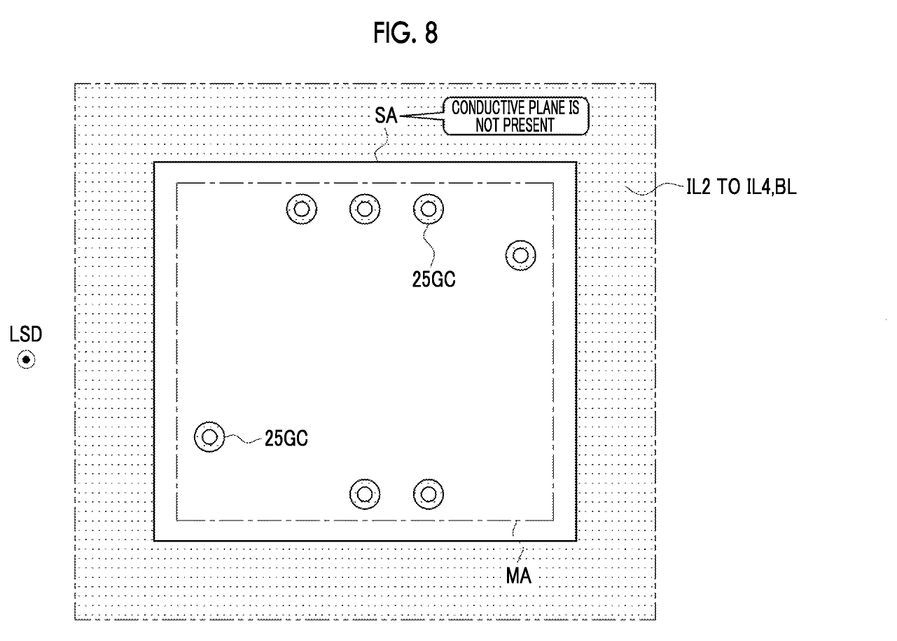

In the first embodiment, the inner layer IL1 functions as a conductive plane in a region other than the clearance regions CA. However, the present disclosed technology is not limited thereto. For example, as shown in FIGS. 7 and 8, a configuration in which at least a conductive plane (the ground plane of the inner layer IL2, the power source plane of the inner layer IL3, and the like) is not present in the specific region SA of the inner layers IL1 to IL4 and the rear layer BL may also be adopted. Only vias 25GC of the gyro sensor 17 are formed in the specific region SA of the inner layers IL2 to IL4 and the rear layer BL, and not only the conductive plane but also the wiring patterns 35G are not present. In addition, methods of realizing a configuration in which no conductive plane is present include a method in which a conductive plane already formed is removed through etching and a method in which no conductive plane is formed from the beginning.

As described above, in the second embodiment, no conductive plane is present in the specific region SA. Since not only the wiring patterns 35G but also a conductive plane that may complicate the vibration characteristics of the multilayer circuit board 15 around the gyro sensor 17 are not present, it is possible to further stabilize the vibration characteristics of the multilayer circuit board 15. Therefore, the output reliability of the gyro sensor 17 and the accuracy of shake correction can be further improved.

A conductive plane transmits heat. In addition, the integrated circuit 18, which is a "heat generating component", is mounted on the multilayer circuit board 15. Therefore, heat of the integrated circuit 18 may be transmitted to the vicinity of the gyro sensor 17 by the conductive plane. In a case where heat of the integrated circuit 18 is transmitted to the vicinity of the gyro sensor 17, the multilayer circuit board 15 is deformed and stress is applied to the gyro sensor 17 due to a difference between thermal expansion factors of the layers of the multilayer circuit board 15, particularly a difference between thermal expansion factors of the surface layer TL, the inner layers IL1 to IL4, the rear layer BL, the prepregs 22, and the core 23, the prepregs 22 and the core 23 being made of resin. In addition, thermal expansion of solder attached to the terminal lands 21G of the gyro sensor 17 also applies stress to the gyro sensor 17. Such unnecessary stress on the gyro sensor 17 results in a decrease in output reliability of the gyro sensor 17 and a decrease in accuracy of shake correction.

Therefore, in a case where no conductive plane is present in the specific region SA, a possibility that heat of the integrated circuit 18 is transmitted to the vicinity of the gyro sensor 17 can be lowered. Therefore, the output reliability of the gyro sensor 17 and the accuracy of shake correction can be further improved. Note that it is also conceivable to mount the integrated circuit 18 on a multilayer circuit board different from a multilayer circuit board on which the gyro sensor 17 is mounted. However, such a method results in an increase in cost and space for the multilayer circuit boards, which is contrary to the demand for cost reduction and size reduction.

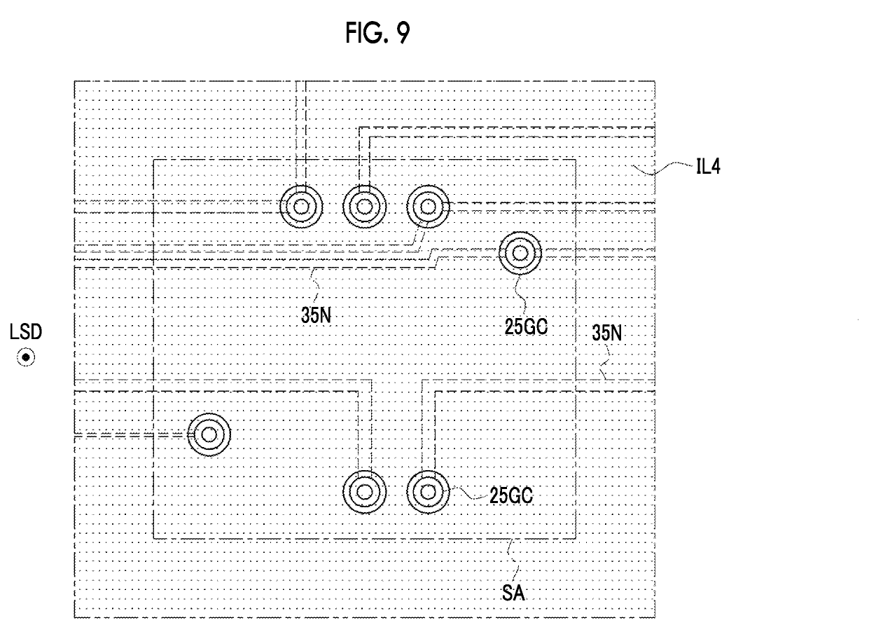

Note that in a case where, for example, wiring patterns 35N, which cause noises, are formed in the specific region SA of the rear layer BL as shown in FIG. 9, the inner layer IL4 may have a configuration in which a conductive plane is present at least in the specific region SA instead of having a configuration in which no conductive plane is present at least in the specific region SA so that the inner layer IL4 functions as a shield. Note that the wiring patterns 35N are, for example, high-speed communication lines or power supply lines. In this manner, it is possible to suppress transmission of noises to the gyro sensor 17, the noises being from the wiring patterns 35N.

### Third Embodiment

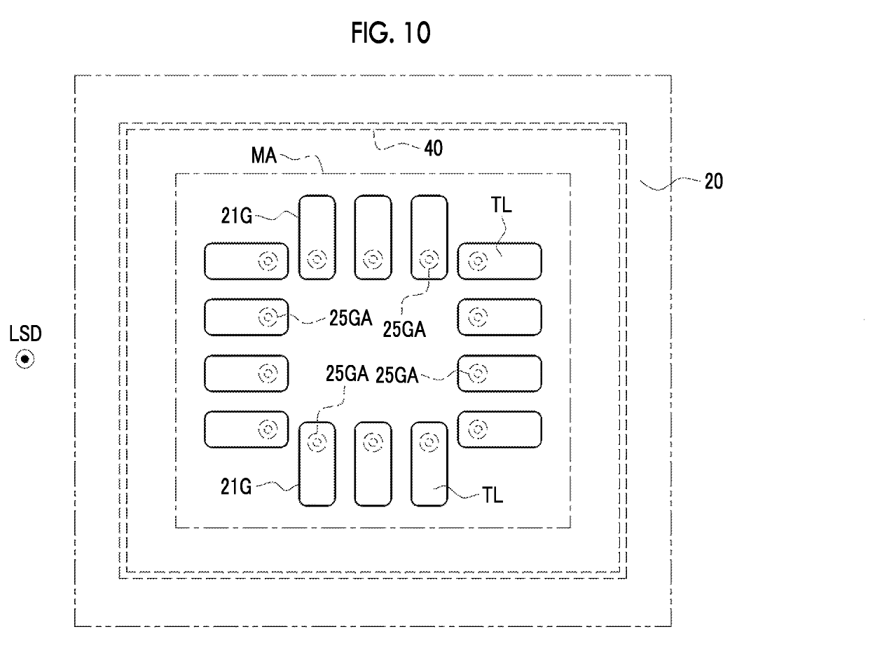

For example, as shown in FIG. 10, a vibration transmission suppressing pattern 40 may be formed around the installation region MA of the surface layer TL. The vibration transmission suppressing pattern 40 is an independent pattern that is connected to no wiring pattern. The vibration transmission suppressing pattern 40 is a quadrangular frame-shaped pattern of which the shape and center are the same as the shape and center of the installation region MA as with the specific region SA and of which the outer shape is a region obtained by multiplying the installation region MA by a set scale factor. The value of the set scale factor is, for example, equal to or greater than 1.5 and less than 2.0. That is, the vibration transmission suppressing pattern 40 is larger than the installation region MA and the specific region SA. With the vibration transmission suppressing pattern 40, it is possible to suppress transmission of vibration to the gyro sensor 17, the vibration being from the outside of the vibration transmission suppressing pattern 40. On the contrary, it is also possible to suppress transmission of vibration of the gyro sensor 17 to the integrated circuit 18 outside the vibration transmission suppressing pattern 40.

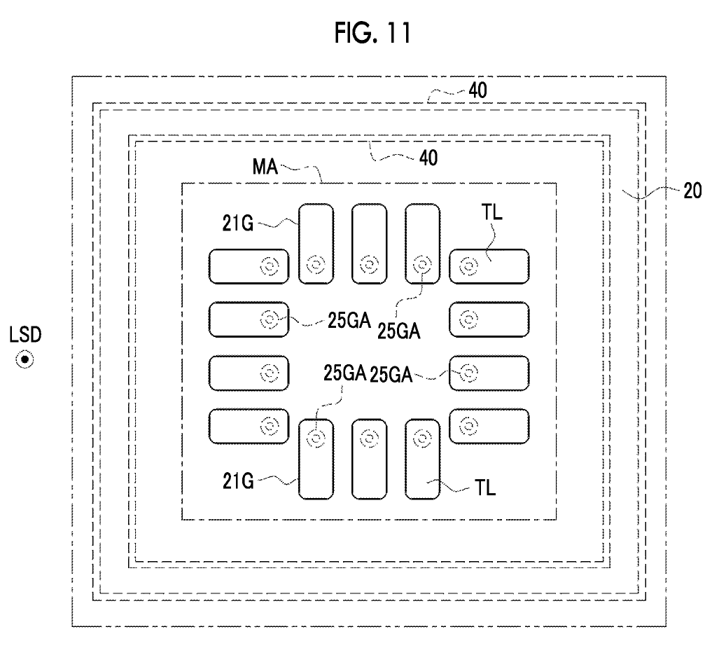

For example, as shown in FIG. 11, two vibration transmission suppressing patterns 40 may be formed. In a case where two vibration transmission suppressing patterns 40 are formed in this manner, an effect in which transmission of vibration is suppressed can be enhanced. Although an example in which two vibration transmission suppressing patterns 40 are formed has been described, more vibration transmission suppressing patterns 40 like three vibration transmission suppressing patterns 40 or four vibration transmission suppressing patterns 40 may also be formed.

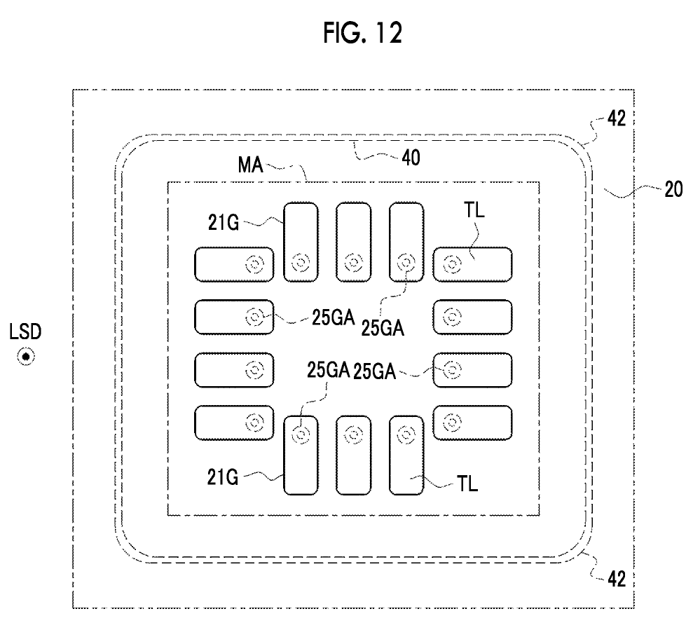

Each of the vibration transmission suppressing patterns 40 shown in FIGS. 10 and 11 has a rectangular shape that conforms to the installation region MA and that has four corners. However, the present disclosed technology is not limited thereto. For example, as shown in FIG. 12, four corners of the vibration transmission suppressing pattern 40 may be rounded so that curved portions 42 are formed. In the case of the vibration transmission suppressing pattern 40 including the curved portions 42, an effect in which transmission of vibration is suppressed can be enhanced in comparison with the case of the vibration transmission suppressing pattern 40 having a shape with four corners. In a case where the vibration transmission suppressing pattern 40 has a circular shape or an oval shape, the entire vibration transmission suppressing pattern 40 is the curved portion 42. Note that the vibration transmission suppressing pattern 40 may be a pattern that continuously surrounds the installation region MA as described above, and may be a pattern that is partially intermittent. In addition, the width of the vibration transmission suppressing pattern 40 at a position at which vibration is likely to be transmitted may be increased, and a plurality of vibration transmission suppressing patterns 40 may be formed only at a position at which vibration is likely to be transmitted.

### Fourth Embodiment

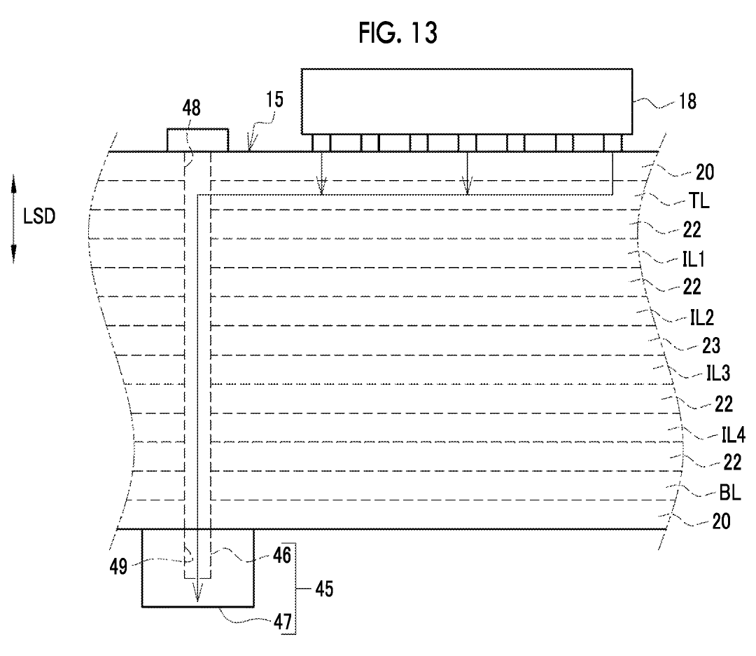

For example, as shown in FIG. 13, a heat radiation mechanism 45 may be provided near the integrated circuit 18 which is a "heat generating component". The heat radiation mechanism 45 is composed of a screw 46 and a heat sink 47. The screw 46 and the heat sink 47 are made of, for example, copper, aluminum, or the like. The screw 46 is screwed into a screw hole 48 that is formed to penetrate all the layers of the multilayer circuit board 15. The screw 46 comes into contact with heat radiation patterns of the surface layer TL, the inner layers IL1 to IL4, and the rear layer BL in the screw hole 48. The heat radiation patterns are formed independently of the wiring patterns 35G, the vibration transmission suppressing pattern 40, and the like.

A screw hole 49 is also formed in the heat sink 47, and a distal end of the screw 46 is screwed into the screw hole 49. As represented by arrows, heat generated in the integrated circuit 18 is mainly transmitted from a heat radiation pattern of the surface layer TL to the screw 46, and is transmitted from the screw 46 to the heat sink 47 to be radiated to the outside via the heat sink 47. With the heat radiation mechanism 45, heat of the integrated circuit 18 can be effectively radiated. The amount of heat of the integrated circuit 18 that is transmitted to the vicinity of the gyro sensor 17 can be reduced. It is possible to lower a possibility that unnecessary stress acts on the gyro sensor 17 due to heat of the integrated circuit 18, and it is possible to further improve the output reliability of the gyro sensor 17 and the accuracy of shake correction. Note that a screw hole 49 may be formed in a chassis of the interchangeable lens 12 and the screw 46 may be screwed into the screw hole 49 instead of the heat sink 47.

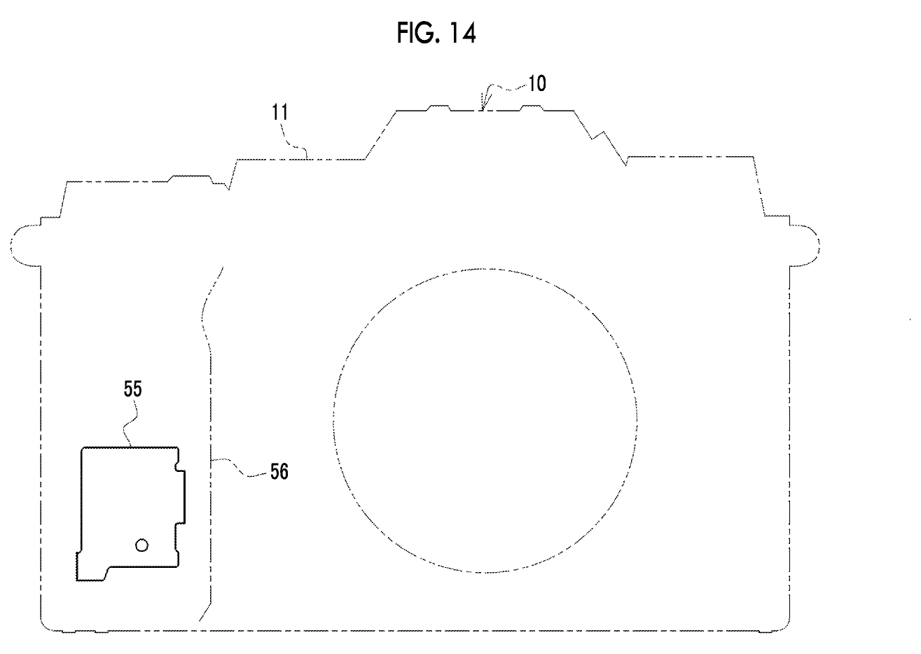

An example in which the multilayer circuit board 15 is built into the interchangeable lens 12 has been described. However, the present disclosed technology is not limited thereto. For example, the multilayer circuit board 15 is built into the imaging apparatus 10 as with a multilayer circuit board 55 shown in FIG. 14. The multilayer circuit board 55 is provided in, for example, a grip portion 56 of the apparatus main body 11 of the imaging apparatus 10.

It is possible to understand the techniques described in the following supplementary notes from the above description.

### Supplementary Note 1

A multilayer circuit board including:

a gyro sensor mounted on a first layer,

in which at least a portion of a wiring pattern routed from a terminal land of the gyro sensor is not formed in a specific region of the first layer, the specific region corresponding to an installation region of the gyro sensor as seen in a lamination direction.

### Supplementary Note 2

The multilayer circuit board according to Supplementary Note 1,

in which the terminal land is formed at the first layer,

the wiring pattern is formed at a layer different from the first layer, and

the terminal land and the wiring pattern are connected to each other via a conduction hole.

### Supplementary Note 3

The multilayer circuit board according to Supplementary Note 1 or 2,

in which a conductive plane is not present in the specific region.

### Supplementary Note 4

The multilayer circuit board according to any one of Supplementary Notes 1 to 3,

in which the specific region includes a region inside the installation region and a region outside the installation region.

### Supplementary Note 5

The multilayer circuit board according to any one of Supplementary Notes 1 to 4,

in which the specific region is a region obtained by multiplying the installation region by a set scale factor.

### Supplementary Note 6

The multilayer circuit board according to any one of Supplementary Notes 1 to 5,

in which the terminal land is formed at the first layer, and

the installation region includes the terminal land.

### Supplementary Note 7

The multilayer circuit board according to any one of Supplementary Notes 4 to 6,

in which a vibration transmission suppressing pattern is formed around the installation region of the first layer.

### Supplementary Note 8

The multilayer circuit board according to Supplementary Note 7,

in which a plurality of vibration transmission suppressing patterns are formed.

### Supplementary Note 9

The multilayer circuit board according to Supplementary Note 7 or 8,

in which the vibration transmission suppressing pattern includes a curved portion.

### Supplementary Note 10

The multilayer circuit board according to any one of Supplementary Notes 1 to 9,

in which a layer that functions as a shield for a wiring pattern causing a noise is provided.

### Supplementary Note 11

The multilayer circuit board according to any one of Supplementary Notes 1 to 10,

in which a heat generating component is mounted on the first layer in addition to the gyro sensor, and

a heat radiation mechanism that radiates heat of the heat generating component to an outside is provided.

### Supplementary Note 12

The multilayer circuit board according to any one of Supplementary Notes 1 to 11,

in which a board fixation portion is provided within a set distance from the gyro sensor.

### Supplementary Note 13

The multilayer circuit board according to any one of Supplementary Notes 1 to 12,

in which the multilayer circuit board is built into an imaging apparatus or an interchangeable lens.

Regarding the present disclosed technology, the above-described various embodiments and/or various modification examples can be combined with each other as appropriate. It is needless to say that the present disclosed technology is not limited to each of the embodiments described above and various configurations can be employed without departing from the gist.

Contents described and illustrated above are for detailed description of a part according to the present disclosed technology and are merely an example of the present disclosed technology. For example, description related to the above-described configurations, functions, actions, and effects is description related to an example of configurations, functions, actions, and effects of a part according to the present disclosed technology. Therefore, it is a matter of course that an unnecessary part of the contents described and illustrated above may be deleted, a new element may be added, and replacement may be made without departing from the point of the present disclosed technology. In addition, in order to avoid complication and facilitate the understanding of a portion according to the present disclosed technology, regarding the contents described and illustrated above, description related to common technical knowledge or the like which does not need to be described to enable implementation of the present disclosed technology has been omitted.

In the present specification, the term “A and/or B” is synonymous with the term “at least one of A or B”. That is, the term “A and/or B” means only A, only B, or a combination of A and B. In addition, in the present specification, the same approach as “A and/or B” is applied to a case where three or more matters are represented by connecting the matters with “and/or”.

All documents, patent applications, and technical standards described in the present specification are incorporated in the present specification by reference to the same extent as in a case where each of the documents, patent applications, and technical standards are specifically and individually indicated to be incorporated by reference.

What is claimed is:

1. A multilayer circuit board comprising:
a gyro sensor mounted on a first layer,
wherein at least a portion of a wiring pattern routed from a terminal land of the gyro sensor is not formed in a specific region of the first layer, the specific region corresponding to an installation region of the gyro sensor as seen in a lamination direction.

2. The multilayer circuit board according to claim 1,
wherein the terminal land is formed at the first layer,
the wiring pattern is formed at a layer different from the first layer, and
the terminal land and the wiring pattern are connected to each other via a conduction hole.

3. The multilayer circuit board according to claim 1,
wherein a conductive plane is not present in the specific region.

4. The multilayer circuit board according to claim 1,
wherein the specific region includes a region inside the installation region and a region outside the installation region.

5. The multilayer circuit board according to claim 1,
wherein the specific region is a region obtained by multiplying the installation region by a set scale factor.

6. The multilayer circuit board according to claim 1,
wherein the terminal land is formed at the first layer, and
the installation region includes the terminal land.

7. The multilayer circuit board according to claim 4,
wherein a vibration transmission suppressing pattern is formed around the installation region of the first layer.

8. The multilayer circuit board according to claim 7,
wherein a plurality of vibration transmission suppressing patterns are formed.

9. The multilayer circuit board according to claim 7,
wherein the vibration transmission suppressing pattern includes a curved portion.

10. The multilayer circuit board according to claim 1,
wherein a layer that functions as a shield for a wiring pattern causing a noise is provided.

11. The multilayer circuit board according to claim 1,
wherein a heat generating component is mounted on the first layer in addition to the gyro sensor, and
a heat radiation mechanism that radiates heat of the heat generating component to an outside is provided.

12. The multilayer circuit board according to claim 1,
wherein a board fixation portion is provided within a set distance from the gyro sensor.

13. An imaging apparatus comprising the multilayer circuit board according to claim 1.

14. An interchangeable lens comprising the multilayer circuit board according to claim 1.
